(19) United States
(12) Patent Application Publication
(10) Pub. No.: US 2026/0308193 A1
(43) Pub. Date: Oct. 8, 2026

(54) NOVEL HALF-SANDWICH COMPLEXES OF RUTHENIUM

(71) Applicant: Heraeus Precious Metals GmbH & Co. KG, HANAU (DE)

(72) Inventors: Michael GOCK, Hanau (DE); Michael UNKRIG-BAU, Hanau (DE); Jan-Niklas HUSTER, Bochum (DE); David ZANDERS, Bochum (DE); Jorit OBENLÜNESCHLOSS, Bochum (DE); Anjana DEVI, Bochum (DE)

(21) Appl. No.: 19/478,510

(22) PCT Filed: Feb. 13, 2024
(86) PCT No.: PCT/EP2024/053562

§ 371 Date: Oct. 24, 2025

(30) Foreign Application Priority Data
Apr. 25, 2023 (EP) 23169704.6

(51) Int. Cl. C07F 17/02

(52) U.S. Cl. CPC C07F 17/02

(57) ABSTRACT

Semi-sandwich complexes of formulas η⁵-C₅H₅₋ₙR1ₙRu(CO)₂CₘH₂ₘNR2R3 and η⁵-C₉H₇₋ₚR1ₚRu(CO)₂CₘH₂ₘNR2R3, wherein: n=0, 1, 2, 3, 4 or 5; m=1, 2, 3, 4 or 5; and, p=0, 1, 2, 3, 4, 5, 6 or 7, the functional group(s) R1 are selected independently of one another from methyl, ethyl, propyl, isopropyl and the isomeric butyl functional groups, and the functional groups R2 and R3 are selected independently of one another from methyl, ethyl, propyl, isopropyl and the isomeric butyl functional groups.

The invention relates to new semi-sandwich complexes of ruthenium which allow for depositing thin ruthenium layers or ruthenium oxide layers as ruthenium precursors by means of CVD or ALD methods (CVD=chemical vapor deposition; ALD=atomic layer deposition) on substrates. The new semi-sandwich complexes can also be used as homogeneous catalysts.

According to the current definition and also in the context of the present patent application, a CVD method is a method in which the vapor of a precursor is fed continuously from a heated reservoir into a reactor space under negative pressure conditions (0.1-10 mbar) and forms a layer there on heated contact surfaces of a substrate, for example contact surfaces of a semiconductor substrate, by thermal decomposition, for example in the temperature range of from 200 to 800° C. This continuous layer growth process can be supported by admixture of a co-reactant and/or by the inflow of an inert carrier gas such as nitrogen or argon.

According to the current definition and also in the context of the present patent application, an ALD method is a method in which the vapor of a precursor is pulsed in sequentially from a heated reservoir under negative pressure conditions (0.01-10 mbar) and in exchange with a co-reactant in a reactor space. There, the contact surfaces of a substrate, for example contact surfaces of a semiconductor substrate, heated to a temperature, for example in the range of >50 to 300° C., then form a layer through self-limiting chemical reactions. Thus, the layer growth does not take place continuously during an ALD process, but rather in cycles. The process can be supported during each pulse by the inflow of an inert carrier gas such as nitrogen or argon.

Ruchi Gaur, Lallan Mishra, M. Aslam Siddiqi, and Burak Atakan in RSC Adv., 2014, 4, 33785-33805 give an overview of ruthenium compounds that are usable for vapor deposition of ruthenium layers.

WO 2009/015270 A1 discloses semi-sandwich complexes of the formula Cp(R)ₙRu(CO)₂(X) with R=C1-C10-alkyl; X=C1-C10-alkyl; and n=1, 2, 3, 4 or 5. WO 2009/015271 A1 discloses the use of such semi-sandwich complexes for depositing a ruthenium film by means of ALD methods.

The object of the invention was to provide ruthenium compounds having improved properties with regard to a use for producing ruthenium oxide layers or ruthenium layers by means of CVD or ALD methods, in particular with regard to a use for producing ruthenium layers by means of CVD or ALD methods in the field of semiconductor production. The ruthenium compounds to be found should have a high volatility with simultaneous thermal stability; in other words, it should be possible for them to be evaporated without decomposition at the lowest possible temperature, in particular in the range of from 50 to 150° C. In the case of a CVD method, said compounds are intended to decompose by thermal treatment at temperatures above the boiling point, where applicable using a co-reactant, or, in the case of an ALD method, by reaction with a co-reactant at the normally prevailing process pressure to form metallic ruthenium, or to lead to the formation of a ruthenium oxide layer. During the decomposition to form metallic ruthenium, it should be possible for them to be deposited rapidly in the form of layers that are as pure as possible without any or with only a few tolerable contaminations by foreign atoms, for example with <3 at. % in each case for carbon, oxygen, or nitrogen content. For the field of semiconductor production, this means that, of the ruthenium compounds to be found, ruthenium metal layers which are as pure as possible are to be deposited by CVD or ALD methods on contact surfaces of semiconductors. The ruthenium compounds to be found should furthermore be liquid at room temperature, sufficiently stable with respect to air and water, not self-igniting, and be able to be synthesized and purified as easily as possible.

The invention achieves the object by providing semi-sandwich complexes selected from the group consisting of compounds of the formulas
η⁵-C₅H₅₋ₙR1ₙRu(CO)₂CₘH₂ₘNR2R3 and η⁵-C₉H₇₋ₚR1ₚRu(CO)₂CₘH₂ₘNR2R3, wherein
n=0, 1, 2, 3, 4 or 5, preferably 0 or 1, in particular 0,
m=1, 2, 3, 4 or 5,
p=0, 1, 2, 3, 4, 5, 6 or 7, preferably 0 or 1, in particular 0,
the functional group(s) R1 are selected independently of one another from methyl, ethyl, propyl, isopropyl and the isomeric butyl functional groups, and
the functional groups R2 and R3 are selected independently of one another from methyl, ethyl, propyl, isopropyl and the isomeric butyl functional groups.

The term “isomeric butyl functional groups” used herein does not include any isomeric butyl functional groups having a cycloaliphatic structural unit.

Semi-sandwich complexes are preferably selected from the group consisting of compounds of the formulas η⁵-C₅H₅₋ₙR1ₙRu(CO)₂CₘH₂ₘNR2R3, wherein
n=0, 1, 2, 3, 4 or 5, preferably 0 or 1, in particular 0,
m=1, 2, 3, 4 or 5,
the functional group(s) R1 are selected independently of one another from methyl, ethyl, propyl, isopropyl and the isomeric butyl functional groups, and
the functional groups R2 and R3 are selected independently of one another from methyl, ethyl, propyl, isopropyl and the isomeric butyl functional groups. Particularly preferred semi-sandwich complexes are those of the formulas η⁵-C₅H₅Ru(CO)₂CₘH₂ₘNR2R3, where m=1, 2, 3, 4 or 5, and the functional groups R2 and R3 are selected independently of one another from methyl and ethyl. Especially preferred are η⁵-C₅H₅Ru(CO)₂C₃H₆N(CH₃)₂ and η⁵-C₅H₅Ru(CO)₂C₃H₆N(CH₂CH₃)₂, more precisely η⁵-C₅H₅Ru(CO)₂(CH₂)₃N(CH₃)₂, i.e., dicarbonyl(η⁵cyclopentadienyl) (3-dimethylaminopropyl) ruthenium and η⁵-C₅H₅Ru(CO)₂(CH₂)₃N(CH₂CH₃)₂, i.e., dicarbonyl (η⁵-cyclopentadienyl) (3-diethylaminopropyl) ruthenium.

The semi-sandwich complexes according to the invention can form dimers or oligomers. This process can be reversible.

The invention also relates to methods for producing the semi-sandwich complexes according to the invention.

A first method for producing a semi-sandwich complex according to the invention selected from the group consisting of compounds of the formulas
η⁵-C₅H₅₋ₙR1ₙRu(CO)₂CₘH₂ₘNR2R3 and η⁵-C₉H₇₋ₚR1ₚRu(CO)₂CₘH₂ₘNR2R3 comprises or consists in the conversion of η⁵C5H₅₋ₙR1ₙRu(CO)₂Hal or
η⁵-C₉H₇₋ₚR1ₚRu(CO)₂Hal with an organometallic compound of type MCₘH₂ₘNR2R3 or of the type Zn(CₘH₂ₘNR2R3)₂ or with a Grignard compound of the type Mg(CₘH₂ₘNR2R3)X, wherein
n=0, 1, 2, 3, 4 or 5, preferably 0 or 1, in particular 0,
m=1, 2, 3, 4 or 5,
p=0, 1, 2, 3, 4, 5, 6 or 7, preferably 0 or 1, in particular 0,
the functional group(s) R1 are selected independently of one another from methyl, ethyl, propyl, isopropyl and the isomeric butyl functional groups,
the functional groups R2 and R3 are selected independently of one another from methyl, ethyl, propyl, isopropyl and the isomeric butyl functional groups,
Hal=Cl, Br or I, preferably Cl,
M=Li, Na or K, and
X=Cl or Br.

The method thus comprises the following steps:
(A1) providing η⁵-C₅H₅₋ₙR1ₙRu(CO)₂Hal or η⁵-C₉H₇₋ₚR1ₚRu(CO)₂Hal and an organometallic compound of type MCₘH₂ₘNR2R3 or of the type Zn(CₘH₂ₘNR2R3)₂ or a Grignard compound of the type Mg(CₘH₂ₘNR2R3)X, and
(A2) converting the η⁵-C₅H₅₋ₙR1ₙRu(CO)₂Hal or
η⁵-C₉H₇₋ₚR1ₚRu(CO)₂Hal provided in step (A1) with the MCₘH₂ₘNR2R3 or Zn(CₘH₂ₘNR2R3)₂ or Mg(CₘH₂ₘNR2R3)X also provided in step (A1) to form
η⁵-C₅H₅₋ₙR1ₙRu(CO)₂CₘH₂ₘNR2R3 or η⁵-C₉H₇₋ₚR1ₚRu(CO)₂CₘH₂ₘNR2R3.

The reaction taking place in step (A2) can be represented using the example of η⁵-C₅H₅₋ₙR1ₙRu(CO)₂CₘH₂ₘNR2R3 as follows:

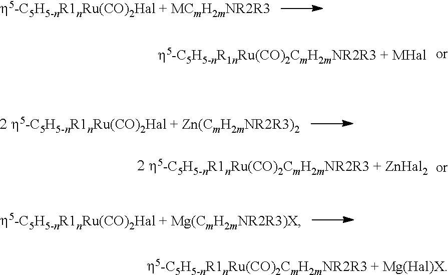

The starting compound mentioned in the above three reaction equations, η⁵-C₅H₅₋ₙR1ₙRu(CO)₂Hal, can be prepared according to or analogously to R. J. Kulawiec, J. W. Faller, and R. H. Crabtree, Organometallics 1990, 9, 745, or S. Dev, J. P. Selegue, J. Organomet. Chem. 1994, 469, 107. The preparation method for η⁵-C₅H₅₋ₙR1ₙRu(CO)₂Hal here comprises the reaction of the commercially available tricarbonyl dichlororuthenium(II) with η⁵-C₅H₅₋ₙR1nTl or with η⁵-C₅H₅₋ₙR1ₙSi(CH₃)₃.

The preparation of the organometallic starting materials of type MCₘH₂ₘNR2R3, Mg(CₘH₂ₘNR2R3)X or Zn(CₘH₂ₘNR2R3)₂ requires no more detailed explanation and is a part of the standard knowledge of the person skilled in the art, i.e., a chemist. The HalCₘH₂ₘNR2R3 required in this regard can be produced from the corresponding commercially available hydrochloride HalCₘH₂ mN⁺HR2R3Cl⁻ by reaction with a base, such as KOH (cf. Example 2 explained below).

For the person skilled in the art, it goes without saying that it is expedient during steps (A1) and in particular (A2) to work with the greatest possible exclusion of water and oxygen. Step (A2) is expediently carried out in aprotic solvent. Suitable reaction temperatures are, for example, in the range of from 10 to 70° C.

Preferred embodiments of the first method according to the aforementioned consist of corresponding methods for producing a semi-sandwich complex according to the invention selected from the group consisting of compounds of the formulas η⁵-C₅H₅₋ₙR1ₙRu(CO)₂CₘH₂ₘNR2R3, in particular with n=0, especially η⁵-C₅H₅Ru(CO)₂(CH₂)₃N(CH₃)₂ or η⁵-C₅H₅Ru(CO)₂(CH₂)₃N(CH₂CH₃)₂.

A second and preferred method for producing a semi-sandwich complex according to the invention selected from the group consisting of compounds of the formulas η⁵-C₅H₅₋ₙR1ₙRu(CO)₂CₘH₂ₘNR2R3 and η⁵-C₉H₇₋ₚR1ₚRu(CO)₂CₘH₂ₘNR2R3 comprises or consists in the conversion of the dimer [η⁵-C₅H₅₋ₙR1ₙRu(CO)₂]₂ or the dimer [η⁵-C₉H₇₋ₚR1ₚRu(CO)₂]₂ with HalCₘH₂ₘNR2R3 in the presence of a reducing agent Y, wherein
n=0, 1, 2, 3, 4 or 5, preferably 0 or 1, in particular 0,
m=1, 2, 3, 4 or 5,
p=0, 1, 2, 3, 4, 5, 6 or 7, preferably 0 or 1, in particular 0,
the functional group(s) R1 are selected independently of one another from methyl, ethyl, propyl, isopropyl and the isomeric butyl functional groups,
the functional groups R2 and R3 are selected independently of one another from methyl, ethyl, propyl, isopropyl and the isomeric butyl functional groups,
Hal=Cl, Br or I, preferably Cl, and
Y is selected from Li, Na, K, Mg, Ca, Zn, H₂, hydrazine, NaK alloy, NaH, lithium naphthalide, sodium naphthalide, potassium naphthalide, NaBH₄ and LiAIH₄.

The method thus comprises the following steps:
(B1) providing [η⁵-C₅H₅₋ₙR1ₙRu(CO)₂]₂ or [η⁵-C₉H₇₋ₚR1ₚRu(CO)₂]₂, HalCₘH₂ₘNR2R3 and Y, and
(B2) reacting the [η⁵-C₅H₅₋ₙR1ₙRu(CO)₂]₂ or [η⁵-C₉H₇₋ₚR1ₚRu(CO)₂]₂ provided in step (B1) with the HalCₘH₂ₘNR2R3 also provided in step (B1) in the presence of the Y also provided in step (B1) to form

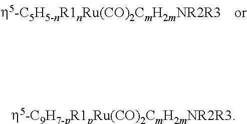

The reducing agent Y thereby reduces the carbon atom directly bonded to Hal.

The reaction can be represented with the example of the formation of η⁵-C₅H₅₋ₙR1ₙRu(CO)₂CₘH₂ₘNR2R3 using sodium as reducing agent Y as follows:

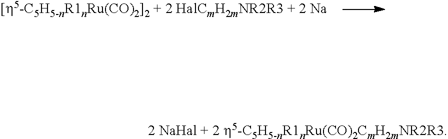

In the example of the formation of η⁵-C₅H₅₋ₙR1ₙRu(CO)₂CₘH₂ₘNR2R3 using sodium naphthalide as reducing agent Y, the reaction can be represented as follows:

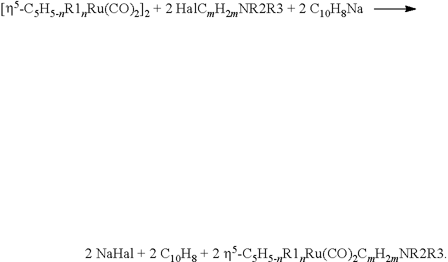

The starting compound mentioned in the two above reaction equations [η⁵-C₅H₅₋ₙR1ₙRu(CO)₂]₂ can be prepared according to or analogously to Kai F. Kalz, Nicole Kindermann, Sheng-Qi Xiang, Andreas Kronz, Adam Lange, and Franc Meyer, Organometallics, 2014, 33, 1475-1479.

Regarding the preparation of HalCₘH₂ₘNR2R3, the aforementioned is applicable.

For the person skilled in the art, it goes without saying that it is expedient during steps (B1) and in particular (B2) to work with the greatest possible exclusion of water and oxygen. Step (B2) is expediently carried out in aprotic solvent. Depending on the reducing agent Y that is selected, appropriate reaction temperatures are, for example, in the range of from −78 to 70° C.

Preferred embodiments of the second method consist, according to the aforementioned, of corresponding methods for producing a semi-sandwich complex according to the invention selected from the group consisting of compounds of the formulas η⁵-C₅H₅₋ₙR1ₙRu(CO)₂CₘH₂ₘNR2R3, in particular with n=0, especially

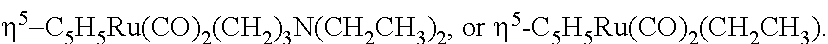

The semi-sandwich complexes according to the invention achieve the object explained at the outset. They can be used as homogeneous catalysts. In particular, they can be used outstandingly as precursors for producing ruthenium layers or ruthenium oxide layers on substrates by means of CVD or ALD methods, in particular ruthenium layers in semiconductor production, i.e., in particular for producing ruthenium layers on contact surfaces of semiconductor substrates. They can be evaporated, more precisely evaporated without decomposition, at atmospheric pressure in the temperature range of from 50 to 150° C. The semi-sandwich complexes η⁵-C₅H₅Ru(CO)₂(CH₂)₃N(CH₃)₂ and η⁵-C₅H₅Ru(CO)₂(CH₂)₃N(CH₂CH₃)₂ according to the invention are in particular suitable for the deposition of a high-purity ruthenium layer on contact surfaces of semiconductor substrates by means of CVD or ALD methods.

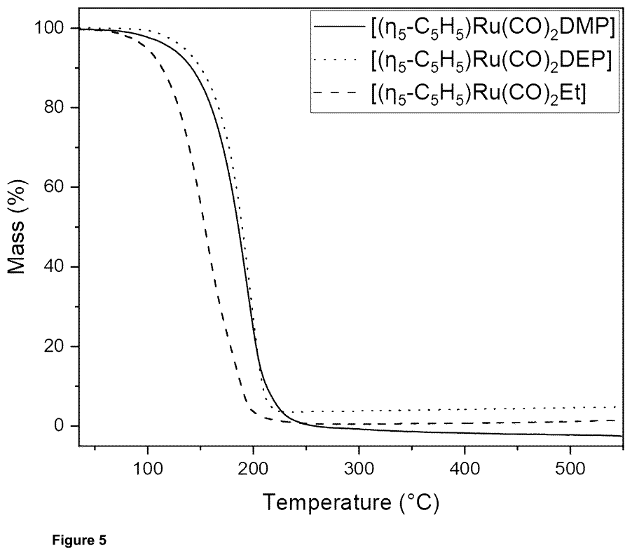

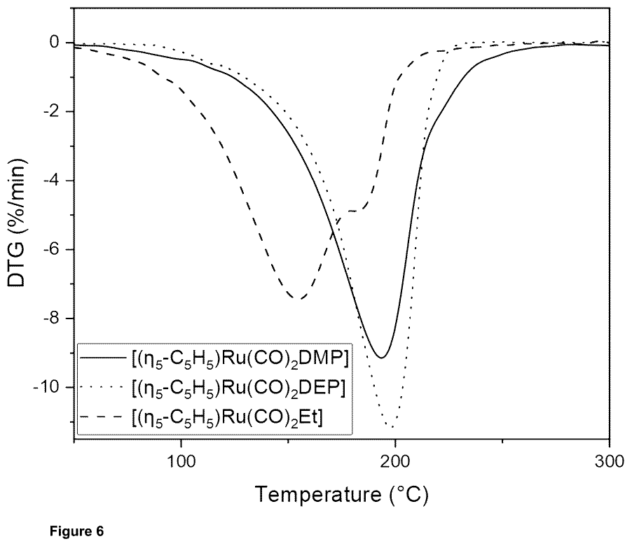

The semi-sandwich complexes according to the invention are superior, with regard to the object explained at the outset, to the aforementioned compounds known from WO 2009/015270 A1 that do not comprise dialkylamino substituents, as shown by a comparison of the semi-sandwich complexes η⁵-C₅H₅Ru(CO)₂(CH₂)₃N(CH₃)₂ and η⁵-C₅H₅Ru(CO)₂(CH₂)₃N(CH₂CH₃)₂ according to the invention to the compound η⁵-C₅H₅Ru(CO)₂(CH₂CH₃) described in WO 2009/015270 A1. From the thermogravimetric analysis of the compounds (cf. FIG. 5), it is apparent that the semi-sandwich complexes according to the invention as well as η⁵-C₅H₅Ru(CO)₂(CH₂CH₃) can be evaporated in the particularly preferred temperature range of from 50 to 150° C. (start of the drop of the curves). The mathematical derivatives of the functions obtained from the thermogravimetric analysis for the analyzed compounds (cf. FIG. 6) clearly show a single minimum in each case for the semi-sandwich complexes according to the invention, and thus only a thermal event, which is to be assigned exclusively to the process of evaporation. By contrast, it is possible to observe for η⁵-C₅H₅Ru(CO)₂(CH₂CH₃) two minima situated close to one another in the curve, and thus two thermal events. On the one hand, these represent the evaporation process, but on the other hand also an additional decomposition event. The semi-sandwich complexes according to the invention thus achieve the object explained at the outset completely and in a manner superior to the not non-decomposed vaporizable compound η⁵-C₅H₅Ru(CO)₂(CH₂CH₃). Such a decomposition process of a ruthenium precursor during the evaporation can typically lead to low-quality layers when producing ruthenium layers or ruthenium oxide layers by vapor deposition. As a result of the decomposition, not only vaporized precursor molecules are located in the gas space, but also decomposition products of the precursor, which no longer follow the same deposition mechanism as the actual precursor molecules, and thus can increase the proportion of foreign atoms in the structured layers. In addition, a more stable process for producing ruthenium layers or ruthenium oxide layers by vapor deposition can be ensured with the semi-sandwich complexes according to the invention. While the compound η⁵-C₅H₅Ru(CO)₂(CH₂CH₃) is decomposed during heating above the boiling point, and thus changes its composition as time progresses, the composition of the semi-sandwich complexes according to the invention remains constant over time. The process parameters selected at the beginning of the deposition process are therefore effective over a long period without adaptation, whereas the process parameters for the compound η⁵-C₅H₅Ru(CO)₂(CH₂CH₃) require adaptation in the course of the deposition process.

### EXAMPLES

All reactions and handling of air- and moisture-sensitive compounds were carried out under a dry argon atmosphere (Air Liquide, 99.995%) by means of a conventional Schlenk technique.

All solvents were dried (MBraun Solvent Purification System) and stored via molecular sieve (4 Å) under an argon atmosphere. All vacuum operations (e.g., solvent removal, sublimation, vacuum distillation) were carried out at a pressure of 10⁻¹ to 10⁻² mbar. Sample preparations for analytical purposes were carried out in a glovebox under an argon atmosphere. All commercially available chemicals were used without further purification.

Analysis of the elements C, H and N was carried out using a CHNS analyzer from Elementar, model Vario Mikro Cube. The Ru content was determined after a microwave digestion on an ICP-OES from Spectro, model Spectro Acros. The oxygen content was calculated by summation of the measurement results of C, H, N, and Ru and difference formation to 100.

A Bruker Avance III 400 NMR spectrometer was used for NMR spectroscopic characterization. All spectra were analyzed using the internal solvent signal (C₆D₅H) and analyzed with the software MestReNova v.10.0.2-15465 of Mestrelab Research S.L.

The IR spectrum was measured on an FT-IR Spectrometer Two from PerkinElmer, located in a glovebox flooded with argon, with a UATR Two ATR unit from PerkinElmer.

Thermogravimetric analyses were carried out at atmospheric pressure on a Netzsch STA 409 PC LUXX, located in a glovebox flooded with argon (sample size about 10 mg), at a heating rate of 5 K/min (N₂, flow rate=300 mL/min).

The isothermal thermogravimetric analysis was carried out on a Netzsch STA 409 PC LUXX at an N₂ gas flow of 90 sccm in a glovebox flooded with argon. The weights for all three isotherms were ~14 mg. After reaching the isothermal temperature (heating rate 10 K/min), the temperature was kept constant. Evaporation rates were derived from the slope of the linear regression. The crucible surface is 0.29706 cm² at a crucible diameter of 0.615 cm.

### Example 1 (Preparing the Reducing Agent Sodium Naphthalide)

1.6 g of naphthalene were dissolved in 50 mL of tetrahydrofurane (THF), and 288 mg of freshly cut sodium pieces were added to this solution at room temperature. The mixture was stirred at room temperature for 20 hours and then used without further workup.

### Example 2 (Preparing N,N-Dimethylaminopropyl Chloride)

N,N-dimethylaminopropyl chloride hydrochloride [Cl(CH₂)₃N⁺H(CH₃)₂Cl⁻] was mixed with 1.9 equivalent KOH (powder, techn.) while being cooled in an ice bath and stirred overnight. The colorless oil obtained was distilled in vacuo to a further 1.9 equiv. KOH (pellets, techn.) (distillation receiver cooled with liquid N₂). The distillate obtained was distilled a second time in vacuo (distillation receiver cooled with liquid N₂), and the resulting oil was used in the following without further workup.

### Example 3 (Alternatives 3a and 3b)

### Inventive Example 3a (Preparing dicarbonyl(η⁵-cyclopentadienyl)(3-dimethylaminopropyl)ruthenium [η⁵-C₅H₅Ru(CO)₂(CH₂)₃N(CH₃)₂ or η⁵-C₅H₅Ru(CO)₂DMP] with sodium naphthalide)

A Schlenk tube was used with a solution of 1.0 g [η⁵-C₅H₅Ru(CO)₂]₂ (prepared according to Kai F. Kalz, Nicole Kindermann, Sheng-Qi Xiang, Andreas Kronz, Adam Lange, and Franc Meyer, Organometallics, 2014, 33, 1475-1479) in 60 mL of THF, and 18.9 mL of the solution of sodium naphthalide from Example 1 are added dropwise with stirring. The mixture obtained was stirred at room temperature for 4 hours. A solution of 548 mg of N,N-dimethylaminopropyl chloride was then added dropwise into 10 mL of THF. The reaction mixture was stirred at room temperature for 20 hours, the solvent was removed under reduced pressure, and the residue was extracted in diethyl ether (5 to 20 hours stirring time). After removal of the diethyl ether in vacuo, the naphthalene still contained in the crude product was removed by sublimation in a vacuum (55° C.). The residue was purified by vacuum distillation, and the product was obtained as an oil (about 30% yield).

### Inventive Example 3b (Preparing dicarbonyl(η⁵-cyclopentadienyl)(3-dimethylaminopropyl)ruthenium [η⁵-C₅H₅Ru(CO)₂(CH₂)₃N(CH₃)₂ or η⁵-C₅H₅Ru(CO)₂DMP] with Na/K alloy)

300 mg of potassium and 100 mg of sodium were weighed into a Schlenk tube, and the liquid Na/K alloy was formed by gentle swinging. The alloy was suspended in 20 mL of THF and admixed with a solution of 1.0 g [η⁵-C₅H₅Ru(CO)₂]₂ (prepared according to Kai F. Kalz, Nicole Kindermann, Sheng-Qi Xiang, Andreas Kronz, Adam Lange, and Franc Meyer, Organometallics, 2014, 33, 1475-1479) in 40 mL THF and stirred at room temperature for 20 h. The solvent was removed under vacuum, and the crude product was admixed with 60 mL of diethyl ether. The mixture was then filtered, admixed with 548 mg of N,N-dimethylaminopropyl chloride at room temperature, and stirred again at room temperature for 20 h. The reaction mixture was filtered again, the solvent was removed under vacuum, and the remaining dark red, oily crude product was distilled under vacuum at 65° C. The product was isolated as a yellowish oil in a yield of 710 mg (51%).

### Elemental Analysis:

C₁₂H₁₇NO₂Ru (308.34 g/mol)

| | C | H | N | O | Ru |
|---|---|---|---|---|---|
| Calculated | | | | | |
| | 46.74% | 5.56% | 4.54% | 10.38% | 32.78% |
| Found | | | | | |
| | 47.03% | 5.62% | 4.53% | 10.85% | 31.97% |

¹H-NMR (200 MHz, C₆D₆): δ (ppm)=4.55 (s, 5H), 2.30 (t, 2H), 2.20 (s, 6H), 1.84 (quint., 2H), 1.76 (t, 2H).

¹³C-NMR (50 MHz, C₆D₆): δ (ppm)=203.4 (2C, η⁵-C₅H₅Ru(QO)₂C₃H₆N(CH₃)₂), 88.8 (5C, η⁵-C₅H₅Ru(CO)₂C₃H₆N(CH₃)₂), 64.6 (1C, η⁵-C₅H₅Ru(CO)₂CH₂CH₂CH₂N(CH₃)₂), 46.1 (2C, η⁵-C₅H₅Ru(CO)₂C₃H₆N(CH₃)₂), 38.2 (1C, η⁵-C₅H₅Ru(CO)₂CH₂CH₂CH₂N(CH₃)₂), −5.7 (1C, η⁵-C₅H₅Ru(CO)₂CH₂CH₂CH₂N(CH₃)₂).

LIFDI-MS (m/z): 308.044=[M]⁺

### Inventive Example 4 (Preparing dicarbonyl(η⁵-cyclopentadienyl)(3-diethylaminopropyl)ruthenium [η⁵-C₅H₅Ru(CO)₂(CH₂)₃N(CH₂CH₃)₂ or η⁵-C₅H₅Ru(CO)₂DEP] with Na/K alloy)

The synthesis was carried out analogously to Example 3b) with the following substances and weights:
300 mg potassium
100 mg sodium
1.0 g [η⁵-C₅H₅Ru(CO)₂]₂
674 mg N,N-diethylaminopropyl chloride

810 mg (54%) of the product were isolated as yellow oil after vacuum distillation at 75° C.

### Elemental Analysis:

CH₂₁NO₂Ru (336.40 g/mol)

| | C | H | N | O | Ru |
|---|---|---|---|---|---|
| Calculated | | | | | |
| | 49.99% | 6.29% | 4.16% | 9.51% | 30.05% |
| Found | | | | | |
| | 49.92% | 6.27% | 4.14% | 9.69% | 29.98% |

¹H-NMR (200 MHz, C₆D₆): δ (ppm)=4.56 (s, 5H), 2.52 (m, 4H+2H), 1.87 (m, 2H), 1.75 (m, 2H), 1.05 (t, 6H).

¹³C-NMR (50 MHz, C₆D₆): δ (ppm)=203.1 (2C, η⁵-C₅H₅Ru(CO)₂C₃H₆N(CH₂CH₃)₂), 88.6 (5C, η⁵-C₅H₅Ru(CO)₂C₃H₆N(CH₂CH₃)₂), 58.1 (1C, η⁵-C₅H₅Ru(CO)₂CH₂CH₂CH₂N(CH₂CH₃)₂), 47.6 (2C, η⁵-C₅H₅Ru(CO)₂C₃H₆N(CH₂CH₃)₂), 37.9 (1C, η⁵-C₅H₅Ru(CO)₂CH₂CH₂CH₂N(CH₂CH₃)₂), 12.6 (2C, η⁵-C₅H₅Ru(CO)₂C₃H₆N(CH₂CH₃)₂), −5.7 (1C, η⁵-C₅H₅Ru(CO)₂CH₂CH₂CH₂N(CH₂CH₃)₂).

LIFDI-MS (m/z): 337.010=[M]⁺

### Comparative example 5 (Preparing dicarbonyl(η⁵-cyclopentadienyl)(ethyl)ruthenium, η⁵-C₅H₅Ru(CO)₂(CH₂CH₃), η⁵-C₅H₅Ru(CO)₂Et with Na/K alloy)

The synthesis was carried out analogously to Example 3b) with the following substances and weights:
300 mg potassium
100 mg sodium
1.0 g [η⁵-C₅H₅Ru(CO)₂]₂
491 mg ethyl bromide

The product was isolated as a yellow oil after vacuum distillation at 65° C.

¹H-NMR (200 MHz, C₆D₆): δ (ppm)=4.53 (s, 5H), 1.87 (q, 2H), 1.52 (t, 3H).

¹³C-NMR (50 MHz, C₆D₆): δ (ppm)=203.1 (2C, η⁵-C₅H₅Ru(CO)₂(CH₂CH₃)), 88.6 (5C, η⁵-C₅H₅Ru(CO)₂(CH₂CH₃)), 30.5 (1C, η⁵-C₅H₅Ru(CO)₂(CH₂CH₃)), −9.8 (1C, η⁵-C₅H₅Ru(CO)₂(CH₂CH₃)).

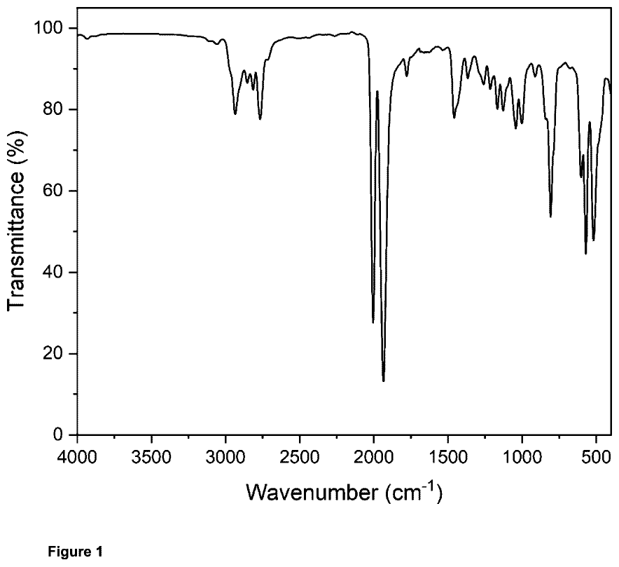

FIG. 1 shows the ATR-IR spectrum of η⁵-C₅H₅Ru(CO)₂(CH₂)₃N(CH₃)₂.

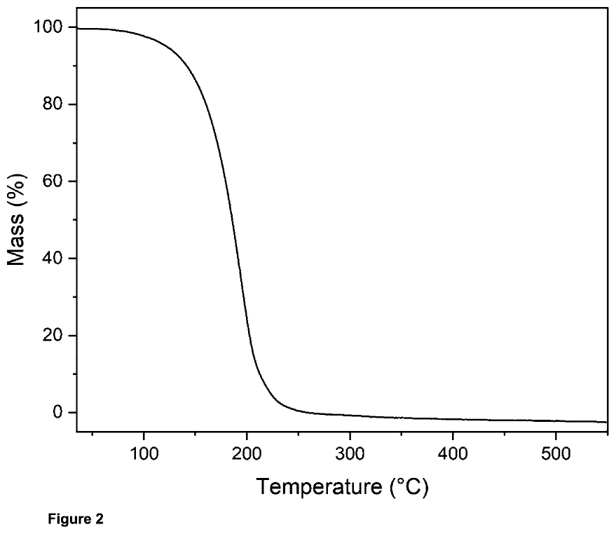

FIG. 2 shows the result of the thermogravimetric analysis of η⁵-C₅H₅Ru(CO)₂(CH₂)₃N(CH₃)₂.

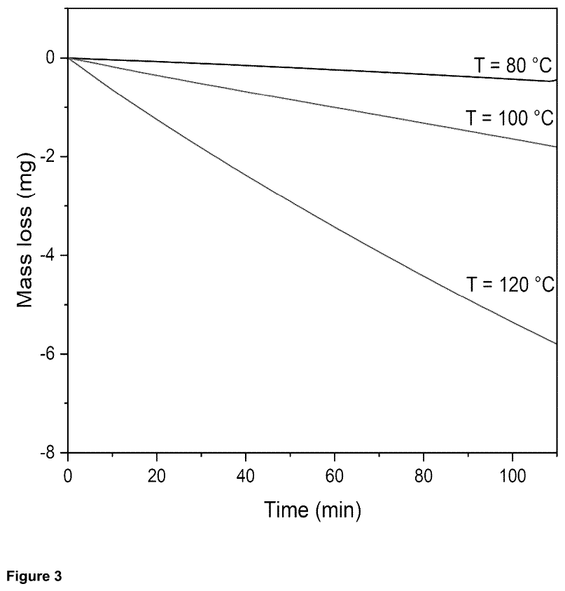

FIG. 3 shows the result of the isothermal gravimetric analysis of η⁵-C₅H₅Ru(CO)₂(CH₂)₃N(CH₃)₂) at 80° C., 100° C., and 120° C. with the evaporation rates E_{80° C.}=15.1 μg/min⁻¹/cm⁻²; E_{100° C.}=54.5 μg/min⁻¹/cm⁻² and E_{120° C.}=176.1 μg/min⁻¹/cm⁻².

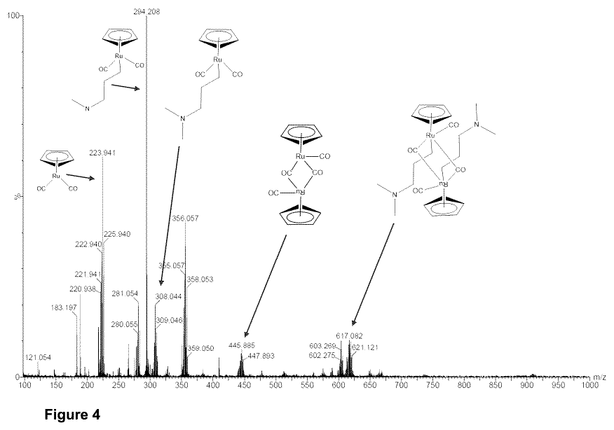

FIG. 4 shows the liquid injection field desorption ionization (LIFDI) mass spectrum from η⁵-C₅H₅Ru(CO)₂(CH₂)₃N(CH₃)₂.

FIG. 5 shows comparative results of the thermogravimetric analyses of

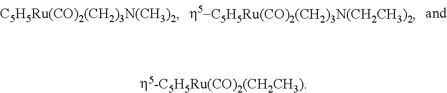

FIG. 6 shows the smoothed derivatives of the functions obtained from the thermogravimetric analyses of η⁵-C₅H₅Ru(CO)₂(CH₂)₃N(CH₃)₂, η⁵-C₅H₅Ru(CO)₂(CH₂)₃N(CH₂CH₃)₂, and η⁵-C₅H₅Ru(CO)₂(CH₂CH₃).

1. Semi-sandwich complexes selected from the group consisting of compounds of the formulas η⁵-C₅H₅₋ₙR1ₙRu(CO)₂CₘH₂ₘNR2R3 and η⁵-C₉H₇₋ₚR1ₚRu(CO)₂CₘH₂ₘNR2R3, wherein
$$n = 0 , 1 , 2 , 3 , 4 or 5 ,$$
$$m = 1 , 2 , 3 , 4 or 5 ,$$
$$p = 0 , 1 , 2 , 3 , 4 , 5 , 6 or 7 ,$$
the functional group(s) R1 are selected independently of one another from methyl, ethyl, propyl, isopropyl and the isomeric butyl functional groups, and
the functional groups R2 and R3 are selected independently of one another from methyl, ethyl, propyl, isopropyl and the isomeric butyl functional groups.

2. The semi-sandwich complexes according to claim 1 selected from the group consisting of compounds of formula η⁵-C₅H₅₋ₙR1ₙRu(CO)₂CₘH₂ₘNR2R3, wherein
$$n = 0 or 1 ,$$
$$m = 1 , 2 , 3 , 4 or 5 ,$$
the functional group(s) R1 are selected independently of one another from methyl, ethyl, propyl, isopropyl and the isomeric butyl functional groups, and
the functional groups R2 and R3 are selected independently of one another from methyl, ethyl, propyl, isopropyl and the isomeric butyl functional groups.

3. The semi-sandwich complexes according to claim 2, wherein n=0, m=1, 2, 3, 4 or 5, and the functional groups R2 and R3 are selected independently of one another from methyl and ethyl.

4. The semi-sandwich complexes η⁵-C₅H₅Ru(CO)₂(CH₂)₃N(CH₃)₂ or η⁵-C₅H₅Ru(CO)₂(CH₂)₃N(CH₂CH₃)₂.

5. The semi-sandwich complexes according to claim 1 in the form of dimers or oligomers.

6. A method for producing a semi-sandwich complex according to claim 1, comprising the conversion of η⁵-C₅H₅₋ₙR1ₙRu(CO)₂Hal or η⁵-C₉H₇₋ₚR1ₚRu(CO)₂Hal with an organometallic compound of the type MCₘH₂ₘNR2R3 or of the type Zn(CₘH₂ₘNR2R3)₂ or with a Grignard compound of the type Mg(CₘH₂ₘNR2R3)X, wherein
$$n = 0 , 1 , 2 , 3 , 4 or 5 ,$$
$$m = 1 , 2 , 3 , 4 or 5 ,$$
$$p = 0 , 1 , 2 , 3 , 4 , 5 , 6 or 7 ,$$
the functional group(s) R1 are selected independently of one another from methyl, ethyl, propyl, isopropyl and the isomeric butyl functional groups,
the functional groups R2 and R3 are selected independently of one another from methyl, ethyl, propyl, isopropyl and the isomeric butyl functional groups,
Hal=Cl, Br or I, preferably Cl,
M=Li, Na or K, and
X=Cl or Br.

7. A method for producing a semi-sandwich complex according to claim 2, comprising the conversion of η⁵-C₅H₅₋ₙR1ₙRu(CO)₂Hal with an organometallic compound of type MCₘH₂ₘNR2R3 or of the type Zn(CₘH₂ₘNR2R3)₂ or with a Grignard compound of the type Mg(CₘH₂ₘNR2R3)X, wherein
$$n = 0 or 1 ,$$
$$m = 1 , 2 , 3 , 4 or 5 ,$$
the functional group(s) R1 are selected independently of one another from methyl, ethyl, propyl, isopropyl and the isomeric butyl functional groups,
the functional groups R2 and R3 are selected independently of one another from methyl, ethyl, propyl, isopropyl and the isomeric butyl functional groups,
$$Hal = Cl , Br or I ,$$
$$M = Li , Na or K , and$$
$$X = Cl or Br .$$

8. The method according to claim 7, wherein n=0, m=1, 2, 3, 4 or 5, and the functional groups R2 and R3 are selected independently of one another from methyl and ethyl.

9. The method according to claim 8, wherein CₘH₂ₘ=(CH₂)₃ and the functional groups R2 and R3 each represent methyl or ethyl.

10. A method for producing a semi-sandwich complex according to claim 1, comprising the reaction of the dimer [η⁵-C₅H₅₋ₙR1ₙRu(CO)₂]₂ or of the dimer [η⁵-C₉H₇₋ₚR1ₚRu(CO)₂]₂ with HalCₘH₂ₘNR2R3 in the presence of a reducing agent Y, wherein
$$n = 0 , 1 , 2 , 3 , 4 or 5 ,$$
$$m = 1 , 2 , 3 , 4 or 5 ,$$
$$p = 0 , 1 , 2 , 3 , 4 , 5 , 6 or 7 ,$$
the functional group(s) R1 are selected independently of one another from methyl, ethyl, propyl, isopropyl and the isomeric butyl functional groups,
the functional groups R2 and R3 are selected independently of one another from methyl, ethyl, propyl, isopropyl and the isomeric butyl functional groups,
$$Hal = Cl , Br or I ,$$
and
Y is selected from Li, Na, K, Mg, Ca, Zn, H₂, hydrazine, NaK alloy, NaH, lithium naphthalide, sodium naphthalide, potassium naphthalide, NaBH₄ and LiAlH₄.

11. A method for producing a semi-sandwich complex according to claim 2, comprising the reaction of the dimer [η⁵-C₅H₅₋ₙR1ₙRu(CO)₂]₂ with HalCₘH₂ₘNR2R3 in the presence of a reducing agent Y, wherein
$$n = 0 or 1 ,$$
$$m = 1 , 2 , 3 , 4 or 5 ,$$
the functional group(s) R1 are selected independently of one another from methyl, ethyl, propyl, isopropyl and the isomeric butyl functional groups,
the functional groups R2 and R3 are selected independently of one another from methyl, ethyl, propyl, isopropyl and the isomeric butyl functional groups;
$$Hal = Cl , Br or I ,$$
and
Y is selected from Li, Na, K, Mg, Ca, Zn, H₂, hydrazine, NaK alloy, NaH, lithium naphthalide, sodium naphthalide, potassium naphthalide, NaBH₄ and LiAlH₄.

12. The method according to claim 11, wherein n=0, m=1, 2, 3, 4 or 5, and the functional groups R2 and R3 are selected independently of one another from methyl and ethyl.

13. The method according to claim 12, wherein CₘH₂ₘ=(CH₂)₃ and the functional groups R2 and R3 each represent methyl or ethyl.

14. A use of a semi-sandwich complex according to any claim 1 for producing a ruthenium layer or a ruthenium oxide layer on a substrate or as a homogeneous catalyst.

15. The use according to claim 14 for producing a ruthenium layer, wherein the substrate is a semiconductor substrate with one or more contact surfaces to be provided with a ruthenium layer.

16. The semi-sandwich complexes according to claim 2 in the form of dimers or oligomers.

17. The semi-sandwich complexes according to claim 3 in the form of dimers or oligomers.

18. The semi-sandwich complexes according to claim 4 in the form of dimers or oligomers.

19. A use of a semi-sandwich complex according to claim 2 or produced according to a method of any of claims 6 to 13 as a precursor in a CVD or ALD process for producing a ruthenium layer or a ruthenium oxide layer on a substrate or as a homogeneous catalyst.

20. A use of a semi-sandwich complex according to claim 3 or produced according to a method of any of claims 6 to 13 as a precursor in a CVD or ALD process for producing a ruthenium layer or a ruthenium oxide layer on a substrate or as a homogeneous catalyst.
